(19) United States
(12) Patent Application Publication
(10) Pub. No.: US 2018/0337206 A1
(43) Pub. Date: Nov. 22, 2018

(54) PACKAGE STRUCTURE AND PACKAGING METHOD

(71) Applicant: China Wafer Level CSP Co., Ltd., Suzhou, Jiangsu (CN)

(72) Inventors: Zhiqi Wang, Suzhou, Jiangsu Province (CN); Fangyuan Hong, Suzhou, Jiangsu Province (CN)

(73) Assignee: China Wafer Level CSP Co., Ltd., Suzhou, Jiangsu (CN)

(21) Appl. No.: 15/755,933

(22) PCT Filed: Aug. 30, 2016
(86) PCT No.: PCT/CN2016/097359

§ 371 Date: Feb. 27, 2018

(30) Foreign Application Priority Data
Sep. 2, 2015 (CN) 201510552404.6
Sep. 2, 2015 (CN) 201520673730.8

(51) Int. Cl. H01L 27/146

(52) U.S. Cl. CPC H01L 27/14623; H01L 27/14618; H01L 27/14687; H01L 27/14685; H01L 27/14636

(57) ABSTRACT

A packaging structure and a packaging method are provided. The packaging structure includes: a chip unit, where a first surface of the chip unit includes a sensing region; an upper cover plate, where a first surface of the upper cover plate is provided with a support structure, the upper cover plate covers the first surface of the chip unit, the support structure is located between the upper cover plate and the chip unit, and the sensing region is located in a cavity enclosed by the support structure and the first surface of the chip unit; and a light shielding layer covering a second surface of the upper cover plate opposite to the first surface of the upper cover plate, where a central region of the second surface which overlaps with the sensing region in a light-transmission direction is exposed through the light shielding layer.

This application claims the priority to Chinese Patent Application No. 201510552404.6, titled “PACKAGE STRUCTURE AND PACKAGING METHOD”, filed on Sep. 2, 2015 with the State Intellectual Property Office of People's Republic of China, and the priority to Chinese Patent Application No. 201520673730.8, titled “PACKAGE STRUCTURE”, filed on Sep. 2, 2015 with the State Intellectual Property Office of People's Republic of China, which are incorporated herein by reference in their entireties.

### FIELD

The present disclosure relates to the technical field of semiconductors, and in particular to a packaging structure and a packaging method.

### BACKGROUND

In the conventional technology, an IC chip is connected with an external circuit by metal wire bonding. With reduction in feature sizes of IC chips and an expansion of scales of integrated circuits, the wire bonding technology is no longer suitable.

The wafer level chip size packaging (WLCSP) technology is a technology of packaging and testing a whole wafer and then cutting the whole wafer to acquire single finished chips, where the size of the packaged chip is the same as the size of a bare chip. The wafer level chip size packaging technology overturns the traditional packaging manners such as the ceramic leadless chip carrier packaging manner and the organic leadless chip carrier packaging manner, and meets market requirements for microelectronic products which are increasingly lighter, smaller, shorter, thinner and cheaper. A chip packaged with the wafer level chip size packaging technology is highly miniaturized, and the cost of the chip is greatly reduced with reduction of the size of the chip and an increase in the size of the wafer. The wafer level chip size packaging technology integrates IC design, wafer fabrication, and package test, and is a focus and a development trend of the current field of packaging.

An image sensor chip includes a sensing region, and is capable of converting an optical image into an electronic signal. In a case where the image sensor chip is packaged using the existing wafer level chip size packaging technology, an upper cover substrate is generally formed on the sensing region for protecting the sensing region from being damaged or contaminated during a packaging process. The upper cover substrate may be retained after the wafer level chip size packaging process is finished for continuing protecting the sensing region from being damaged or contaminated during use of the image sensor chip.

However, the image sensor formed by the above wafer level chip size packaging technology exhibits poor performance.

### SUMMARY

An issue addressed by the present disclosure is that an image sensor formed by the conventional technology exhibits poor performance.

To address the above issue, a packaging structure is provided according to an embodiment of the present disclosure, which includes: a chip unit, where a first surface of the chip unit includes a sensing region; an upper cover plate, where a first surface of the upper cover plate is provided with a support structure, the upper cover plate covers the first surface of the chip unit, the support structure is located between the upper cover plate and the chip unit, and the sensing region is located in a cavity enclosed by the support structure and the first surface of the chip unit; and a light shielding layer covering a second surface of the upper cover plate opposite to the first surface of the upper cover plate, where a central region of the second surface which overlaps with the sensing region in a light-transmission direction is exposed through the light shielding layer.

Optionally, an area of the central region of the upper cover plate which is exposed through the shielding layer may be greater than or equal to an area of the sensing region.

Optionally, the shielding layer may further cover a portion of a sidewall of the upper cover plate.

Optionally, the light shielding layer may be made of a black photosensitive organic material, and a thickness of the light shielding layer may range from 10 μm to 50 μm.

Optionally, the light shielding layer may be made of metal, and a thickness of the light shielding layer may range from 1 μm to 10 μm.

Optionally, the light shielding layer may be made of aluminum.

Optionally, a surface of the metal may be blackened.

Optionally, the chip unit may further include: a contact pad located outside the sensing region; a through hole extending through the chip unit from a second surface of the chip unit opposite to the first surface of the chip unit, where the contact pad is exposed through the through hole; an insulation layer covering the second surface of the chip unit and a surface of a sidewall of the through hole; a metal layer located on a surface of the insulation layer and electrically connected to the contact pad; a solder mask located on a surface of the metal layer and the surface of the insulation layer, where the solder mask is provided with an opening through which a portion of the metal layer is exposed; and a protrusion for external connection by which the opening is filled, where the protrusion for external connection is exposed outside a surface of the solder mask.

Corresponding to the above-mentioned packaging structure, a packaging method is further provided according to an embodiment of the present disclosure, which includes: providing a wafer to be packaged, where a first surface of the wafer to be packaged includes multiple chip units and cutting channel regions located between the multiple chip units, and each of the multiple chip units includes a sensing region; providing a cover substrate, where multiple support structures are formed on a first surface of the cover substrate, and the support structures correspond to the sensing regions on the wafer to be packaged; attaching the first surface of the cover substrate with the first surface of the wafer to be packaged, where cavities are formed by the support structures and the first surface of the wafer to be packaged, and the sensing regions are located in the cavities; forming a light shielding material layer on a second surface of the cover substrate opposite to the first surface of the cover substrate, where the light shielding material layer includes openings corresponding to the sensing regions; and cutting the wafer to be packaged, the cover substrate, and the light shielding material layer along the cutting channel regions, to form multiple packaging structures, where each of the multiple packaging structures includes the chip unit, the upper cover plate formed by cutting the cover substrate, and the light shielding layer formed by cutting the light shielding material layer, the light shielding layer covers the second surface of the upper cover plate, and a central region of the second surface which overlaps with the sensing region in a light-transmission direction is exposed through the light shielding layer.

Optionally, the cutting the wafer to be packaged, the cover substrate, and the light shielding material layer along the cutting channel regions may include: performing a first cutting process, which includes cutting the wafer to be packaged along the cutting channel regions from a second surface of the wafer to be packaged opposite to the first surface of the wafer to be packaged until the first surface of the wafer to be packaged is reached, to form a first cutting groove; and performing a second cutting process, which includes cutting the light shielding material layer and the cover substrate to form a second cutting groove connected with the first cutting groove, and form multiple packaging structures.

Optionally, the cutting the wafer to be packaged, the cover substrate, and the light shielding material layer along the cutting channel regions may further include: performing, before performing the second cutting process, a third cutting process including cutting the cover substrate along the cutting channel regions from the second surface of the cover substrate until a preset depth is reached, to form a third cutting groove, where: the light shielding material layer formed on the second surface of the cover substrate covers a sidewall of the third cutting groove, the second cutting groove formed by cutting the light shielding material layer and the cover substrate with the second cutting process is connected with the first cutting groove and the third cutting groove, a width of the second cutting groove is less than a width of the third cutting groove, and the light shielding layer further covers an upper portion of a sidewall of the upper cover plate after the multiple packaging structures are formed.

Optionally, the light shielding material layer may be made of a black photosensitive organic material, and the forming the light shielding material layer on the second surface of the cover substrate may include: forming a black photosensitive organic material layer on the second surface of the cover substrate, by a spin coating process, a spraying process, or an adhesion process; exposing and developing the black photosensitive organic material layer, to form openings corresponding to the sensing regions in the black photosensitive organic material layer; and baking the black photosensitive organic material layer for hardening the black photosensitive organic material layer.

Optionally, the light shielding material layer may be made of metal, and the forming the light shielding material layer on the second surface of the cover substrate may include: forming a metal material layer on the second surface of the cover substrate by a sputtering process; forming a patterned photoresist layer on the metal material layer, where regions of the metal material layer at which the openings are to be formed are exposed through the patterned photoresist layer; etching the metal material layer with the patterned photoresist layer as a mask, until the second surface of the cover substrate is exposed, to form the openings corresponding to the sensing regions; and removing the patterned photoresist layer.

Optionally, the packaging method may further include: blackening a surface of the metal material layer using an acid solution or an alkali solution.

Optionally, each of the multiple chip units may further include a contact pad located outside the sensing region, and after attaching the first surface of the cover substrate with the first surface of the wafer to be packaged, the packaging method may further include: thinning the wafer to be packaged from a second surface of the wafer to be packaged opposite to the first surface of the wafer to be packaged; etching the wafer to be packaged from the second surface of the wafer to be packaged, to form through holes through which the contact pads of the multiple chip units are exposed; forming an insulation layer on the second surface of the wafer to be packaged and surfaces of sidewalls of the through holes; forming a metal layer connected to the contact pads on a surface of the insulating layer; forming a solder mask on a surface of the metal layer and the surface of the insulation layer, where the solder mask includes openings through which a portion of the surface of the metal layer is exposed; and forming protrusions for external connection on a surface of the solder mask, where the openings are filled by the protrusions for external connection.

As compared with the conventional technology, the technical solution according to the embodiments of the present disclosure has following advantages.

The packaging structure according an embodiment of the present disclosure includes the chip unit, the upper cover plate, and the light shielding layer located on the second surface of the upper cover plate. A peripheral region of the second surface of the upper cover plate is covered by the light shielding layer, and the central region corresponding to the sensing region is exposed through the light shielding layer. As compared with a packaging structure according to the conventional technology, the light shielding layer in the packaging structure according to the embodiment of the present disclosure can block light incident through the peripheral region of the second surface of the upper cover plate, which is prone to be reflected by the side wall of the upper cover plate and enter the sensing region of the chip unit, thereby disturbing imaging of the sensing region. With the light shielding layer according to the embodiments of the present disclosure, the above interfering light is reduced, thereby improving an imaging quality of the package structure serving as an image sensor.

Additionally, in the packaging structure according to the embodiment of the present disclosure, the light shielding layer may further cover a portion of the sidewall of the upper cover plate, thereby further reducing the interfering light incident through the side wall of the upper cover plate, thus the imaging quality of the packaging structure is improved.

Correspondingly, the packaging method according to the embodiments of the present disclosure for forming the above-mentioned packaging structure also has the above-mentioned advantages.

### BRIEF DESCRIPTION OF THE DRAWINGS

FIG. 1 shows a cross-sectional view illustrating a structure of an image sensor chip according to the conventional technology;

FIG. 2 shows a cross-sectional view illustrating a structure of a packaging structure according to an embodiment of the present disclosure;

FIG. 3 shows a cross-sectional view illustrating a structure of a packaging structure according to another embodiment of the present disclosure;

FIGS. 4 to 11 show schematic structural diagrams of intermediate structures formed during implementation of a packaging method according to an embodiment of the present disclosure; and

FIGS. 12 to 15 show schematic structural diagrams of intermediate structures formed during implementation of a packaging method according to another embodiment of the present disclosure.

### DETAILED DESCRIPTION

From the technical background, it can be seen that an image sensor formed by the conventional technology exhibits poor performance.

The inventor of the present disclosure studies a process of packaging image sensor chips using the conventional wafer level chip size packaging technology, and finds that the image sensor chips formed using the conventional technology exhibit poor performance, since light incident on the sensing region is disturbed by an upper cover substrate formed above the sensing region during the chip packaging procedure, which reduces the imaging quality.

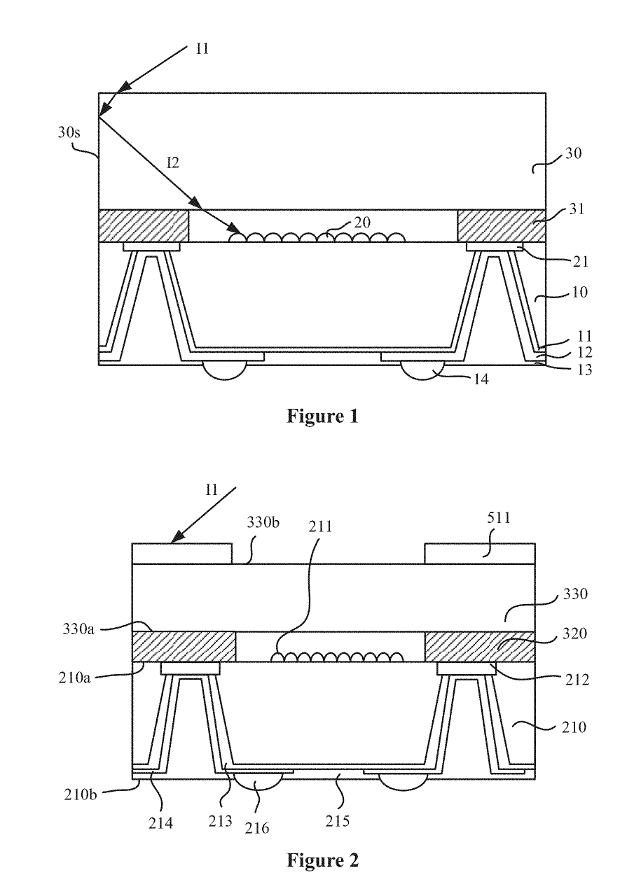

Specifically, reference is made to FIG. 1, which shows a cross-sectional view illustrating a structure of an image sensor chip formed using the conventional technology. The image sensor chip includes: a substrate 10; a sensing region 20 located on a first surface of the substrate 10; contact pads 21 located on the first surface of the substrate 10 on both sides of the sensing region 20; through holes (not indicated in FIG. 1) extending through the substrate 10 from a second surface opposite to the first surface of the substrate 10, where the contact pads 21 are exposed through the through holes; an insulation layer 11 located on side walls of the through holes and the second surface of the substrate 10; a wiring layer 12 covering the contact pads 21 and a portion of the insulation layer 11 from the second surface; a solder mask 13 covering the wiring layer 12 and the insulation layer 11, where the solder mask 13 includes openings; solder balls 14 which are located in the openings of the solder mask 13 and electrically connected with the contact pads 21 via the wiring layer 12; a cavity wall 31 located around the sensing region 20 and on the first surface of the substrate 10; and an upper cover substrate 30 located on the cavity wall. A cavity is formed by the upper cover substrate 30, the cavity wall 31, and the first surface of the substrate 10, so that the sensor 20 is located in the cavity, thereby preventing the sensing region 20 from being contaminated or damaged during packaging and use. The upper cover substrate 30 generally has a great thickness such as 400 μm.

The inventor of the present disclosure found that, during use of the above image sensor chip, when light I1 is incident on the upper cover substrate 30 of the image sensor, a portion of the light which enters the upper cover substrate 30, which is denoted by I2, is incident on a side wall 30s of the upper cover substrate 30, and is refracted and reflected. If the reflected light is incident on the sensing region 20, imaging by the image sensor is disturbed. Specifically, in a case where an incident angle of the light I2 meets a certain condition, for example, in a case where the upper cover substrate 30 is made of glass and air is outside the glass, and the incident angle of the light I2 is greater than a critical angle at the glass to air interface, the light I2 is totally reflected by the side wall 30s of the upper cover substrate 30. The totally reflected light I2, which propagates within the upper cover substrate 30 and is incident on the sensing region 20, causes serious disturbance to the sensing region 20. In an imaging procedure of an image sensor, the disturbance results in a virtual image formed in a direction opposite to an optical path of the totally reflected light I2, which causes reduction in the imaging quality.

In addition, with the trend of miniaturization of the wafer level chip size package, an increasing number of sensor chip packages are integrated on a wafer level chip, and the size of single finished chip packages is decreased, resulting in a decreased distance from the side wall of the upper cover substrate 30 to an edge of the sensing region 20. In this case, the above disturbance is more serious.

Based on the above research, a packaging structure and a packaging method for forming the packaging structure are provided according to the embodiments of the present disclosure. The packaging structure includes a chip unit, an upper cover plate, and a light shielding layer located on a surface of the upper cover plate. A peripheral region of the surface of the upper cover plate is covered by the light shielding layer, and the central region of the surface of the upper cover plate corresponding to the sensing region is exposed through the light shielding layer. Therefore, light incident through the peripheral region of the upper cover plate can be blocked, and interfering light entering the sensing region of the chip unit can be reduced, thereby improving an imaging quality of the sensing region. Correspondingly, the packaging method for forming the above-mentioned packaging structure also has the above advantages.

To make the above object, features and advantages of the present disclosure more apparent and easier to be understood, specific embodiments of the present disclosure are illustrated in detail in conjunction with the drawings hereinafter.

It is to be noted that, the objective of providing the drawings is to help understanding embodiments of the present disclosure, and should not be construed to unduly limit the present disclosure. For the purpose of clarity, the dimensions in the drawings are not drawn to scale, and may be enlarged, reduced or changed in other manners.

First, a packaging structure is provided according to an embodiment of the present disclosure. Referring to FIG. 2, the packaging structure includes: a chip unit 210, where the chip unit 210 includes a first surface 210a and a second surface 210b opposite to the first surface 210a, and the first surface 210a includes a sensing region 211; an upper cover plate 330, where the upper cover plate 330 includes a first surface 330a and a second surface 330b opposite to the first surface 330a, the first surface 330a is provided with a support structure 320, the upper cover plate 330 covers the first surface 210a of the chip unit 210, the support structure 320 is located between the upper cover plate 330 and the chip unit 210, and the sensing region 211 is located in a cavity enclosed by the support structure 320 and the first surface 210a of the chip unit 210; and a light shielding layer 511, where the light shielding layer 511 covers the second surface 330b of the upper cover plate 330, a central region of the second surface 330b overlapping with the sensing region 211 in a light-transmission direction is exposed through the light shielding layer 511. In some embodiments, an area of the central region of the second surface 330b of the upper cover plate 330 which is exposed through the light shielding layer 511 is equal to or greater than an area or the sensing region 211.

In an embodiment of the present disclosure, the light shielding layer 511 is made of a black photosensitive organic material or blackened metal, and is opaque or has low transparency. For example, the light shielding layer 511 may be a black sealant, or blackened aluminum, so that light does not undergo specular reflection at a surface of the light shielding layer 511, thereby providing good light shielding performance. Light incident on the surface of the light shielding layer 511 cannot pass through the light shielding layer 511 and enter the upper cover plate 330.

The packaging structure according to an embodiment of the present disclosure, as shown in FIG. 2, is compared with the image sensor according to the conventional technology shown in FIG. 1, where the same incident light I1 is taken as an example. In FIG. 1, the light I1 enters the upper cover substrate 30 of the image sensor, is reflected by the sidewall 30s of the upper cover substrate 30 and incident on the sensing region 20, and interferes with imaging of the sensing region 20. However, as shown FIG. 2, in the packaging structure according to an embodiment of the present disclosure, the peripheral region of the second surface 330b of the upper cover plate 330 is covered by the light shielding layer 511. Since the light shielding layer 511 is opaque, the light I1 does not enter the upper cover plate 330, and does not cause interference to the sensing region 211. In addition, according to an embodiment of the present disclosure, the area of the central region of the second surface 330b of the upper cover plate 330 which is exposed through the light shielding layer 511 is greater than or equal to an area of the sensing region 211. Therefore, light incident through the central region of the second surface 330b of the upper cover plate 330 passes through the upper cover plate 330 and is incident on the sensing region 211, thereby reducing interference with the imaging quality of the sensing region 211 caused by the light shielding layer 511.

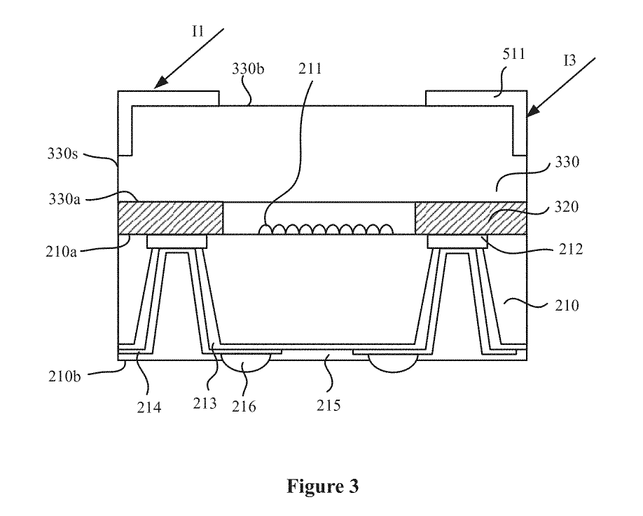

Further, referring to FIG. 3, in some other embodiments, the light shielding layer 511 further covers a portion of a sidewall 330s between the first surface 330a and the second surface 330b of the upper cover plate 330. As compared with the light shielding layer shown in FIG. 2, the light shielding layer 511 covering an upper portion of the sidewall 330s as shown in FIG. 3 can further reduce interfering light I3 incident through the side wall 330s, thereby further improving the imaging quality of the sensing region 211. A height of the upper portion of the sidewall 330s of the upper cover plate 330 covered by the light shielding layer 511 ranges from ⅕ to ⅘ of a thickness of the upper cover plate 330. In a case that the height of the upper portion of the sidewall 330s of the upper cover plate 330 covered by the light shielding layer 511 is too small, an effect of shielding the interfering light incident through the sidewall 330s is limited. In addition, interfering light incident through a lower portion of the sidewall 330s generally cannot reach the sensing region 211. Therefore, an excessively great height of the upper portion of the sidewall 330s covered by the light shielding layer 511 is unnecessary.

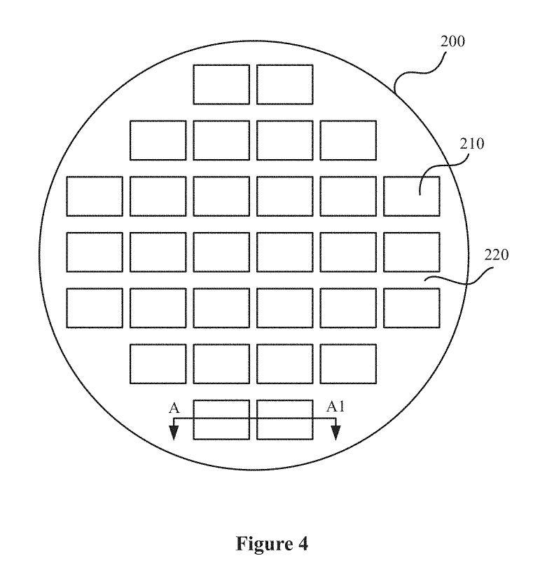

Correspondingly, a packaging method for forming the packaging structure shown in FIG. 2 is provided according to an embodiment of the present disclosure. Reference is made to FIGS. 4 to 11, which are schematic structural diagrams of intermediate structures formed in a packaging process using the packaging method according to an embodiment of the present disclosure.

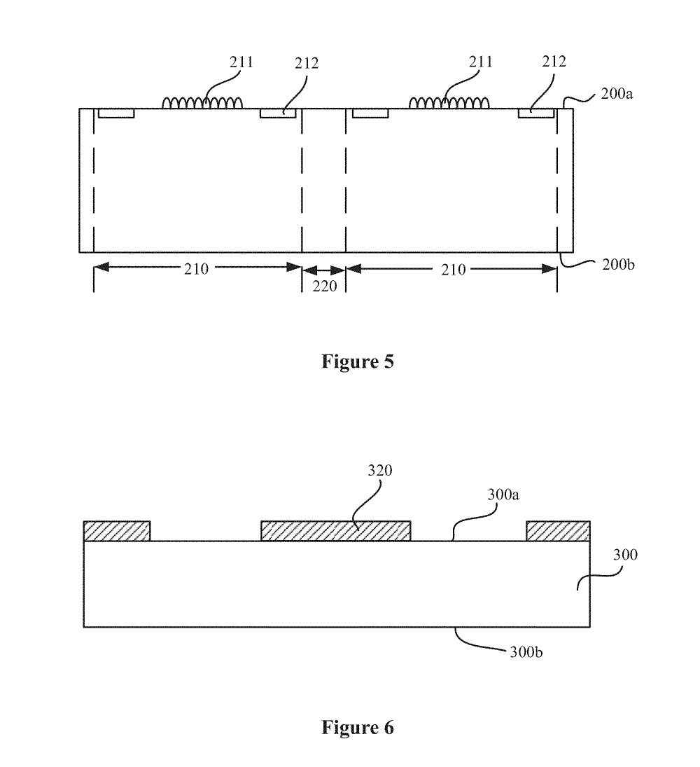

First, referring to FIGS. 3 and 4, a wafer to be packaged 200 is provided. FIG. 4 is a plane view showing a structure of the wafer to be packaged 200. FIG. 5 is a section view taken along AA1 in FIG. 4.

The wafer to be packaged 200 includes a first surface 200a and a second surface 200b opposite to the first surface 200a. The first surface 200a of the wafer to be packaged 200 is provided with multiple chip units 210 and cutting channel regions 220 located between the chip units 210.

In this embodiment, the multiple chip units 210 on the wafer to be packaged 200 are arranged in an array, and the cutting channel regions 220 are located between adjacent chip units 210. The wafer to be packaged 200 is subsequently cut along the cutting channel regions 220, to form multiple chip packaging structures, each of which includes the chip unit 210.

In this embodiment, the chip unit 210 is an image sensor chip unit, and includes a sensing region 211 and a contact pad 212 located outside the sensing regions 211. The sensing region 211 is an optical sensing region, and may be formed, for example, by multiple photodiodes arranged in an array, where the photodiode can convert an optical signal incident on the sensing region 211 into an electrical signal. The contact pad 212 serves as an input terminal and an output terminal through which a component in the sensing region 211 is connected to an external circuit. In some embodiments, the chip unit 210 is formed on a silicon substrate, and further includes other functional components formed within the silicon substrate.

It should be noted that, for clearance, only the section view of the wafer to be packaged 200 taken along AA1 as shown in FIG. 4 is taken as an example for illustration in subsequent steps of the packaging method according to the embodiment of the present disclosure, and similar process steps are performed in other regions.

Next, referring to FIG. 5, a cover substrate 300 is provided. The cover substrate 300 includes a first surface 300a and a second surface 300b opposite to the first surface 300a. Multiple support structures 320 are formed on the first surface 300a of the cover substrate 300. Groove structures formed by the support structures 320 and the first surface 300a of the cover substrate 300 correspond to the sensing regions 211 on the wafer to be packaged 200.

In this embodiment, the cover substrate 300 covers the first surface 200a of the wafer to be packaged 200 in subsequent processes for protecting the sensing regions 211 on the wafer to be packaged 200. Light needs to pass through the cover substrate 300 before reaching the sensing regions 211. Therefore, the cover substrate 300 is made of a transparent material which has high transparency. Both surfaces 300a and 300b of the cover substrate 300 are flat and smooth, and do not cause scattering and diffuse reflection of incident light.

Specifically, the cover substrate 300 may be made of inorganic glass, organic glass or another transparent material with certain strength. In an embodiment of the present disclosure, a thickness of the cover substrate 300 ranges from 300 μm to 500 μm, and for example, may be 400 μm. In a case that the thickness of the cover substrate 300 is too great, a thickness of the formed chip packaging structure is too great and cannot meet the requirement for light and thin electronic products. In a case that the thickness of the cover substrate 300 is too small, strength of the cover substrate 300 is reduced and the cover substrate 300 is prone to break. Therefore, the cover substrate 300 cannot provide sufficient protection to the sensing region subsequently covered by the cover substrate 300.

In some embodiments, the support structures 320 are formed by depositing a support structure material layer on the first surface 300a of the cover substrate 300 and etching the support structure material layer. Specifically, the support structure material layer (not shown) covering the first surface 300a of the cover substrate 300 is first formed, then the support structure material layer is patterned, and a part of the support structure material layer is removed to form the support structures 320. Positions of the groove structures formed by the support structures 320 and the first surface 300a of the cover substrate 300 on the cover substrate 300 correspond to positions of the sensing regions 211 on the wafer to be packaged 200, so that the sensing regions 211 can be located in the grooves enclosed by the support structures 320 and the first surface 300a of the cover substrate 300 after a subsequent attaching process is performed. In some embodiments, the support structure material layer is made of wet film photoresist or dry film photoresist, and is formed by a spraying process, a spin coating process, an adhesion process or the like. The support structures 320 are formed by patterning the support structure material layer through exposure and development. In some embodiments, the support structure material layer may also be formed with an insulating dielectric material such as silicon oxide, silicon nitride, and silicon oxynitride, by a deposition process, and is subsequently patterned using a photolithographic process and an etching process to form the support structures 320.

In some other embodiments, the support structures 320 may also be formed by etching the cover substrate 300. Specifically, a patterned photoresist layer may be formed on the cover substrate 300. Then, the cover substrate 300 is etched with the patterned photoresist layer as a mask, to form the support structures 320 in the cover substrate 300. The support structures 320 are raised portions on the first surface 300a of the cover substrate 300.

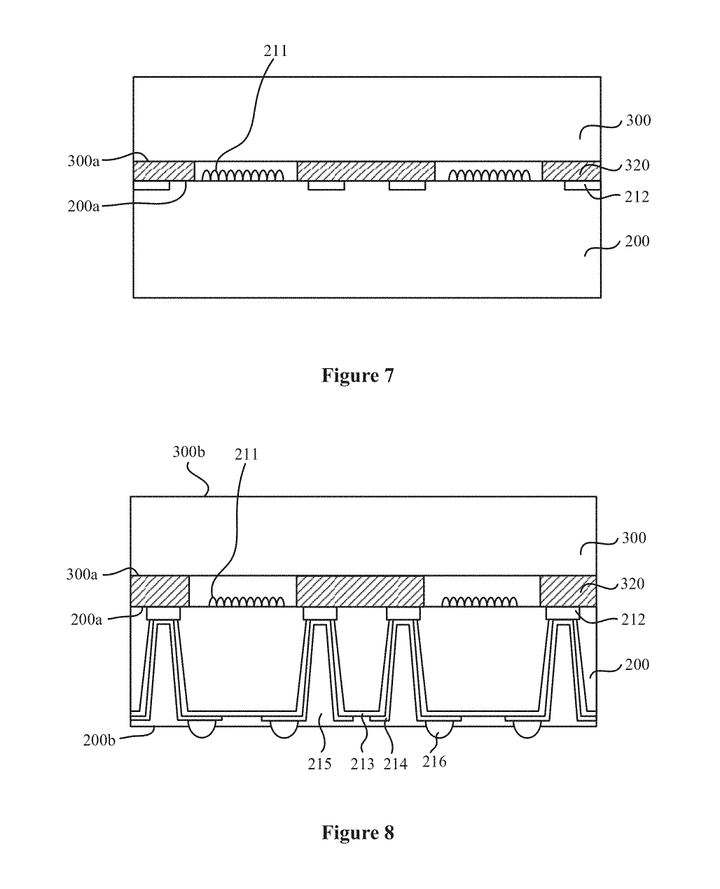

Next, reference is made to FIG. 7. The first surface 300a of the cover substrate 300 is attached with the first surface 200a of the wafer to be packaged 200, so that cavities (not indicated) are formed by the support structures 320 and the first surface 200a of the wafer to be packaged 200, and the sensing regions 211 are located in the cavities.

In this embodiment, the cover substrate 300 is attached with the wafer to be packaged 200 through an adhesive layer (not shown). For example, the adhesive layer may be formed on top surfaces of the support structures 320 on the first surface 300a of the cover substrate 300, and/or on the first surface 200a of the wafer to be packaged 200 by a spraying process, a spin coating process, or an adhesion process. Then, the first surface 300a of the cover substrate 300 is attached with the first surface 200a of the wafer to be packaged 200 through the adhesive layer. The adhesive layer performs an adhesive function, an insulation function and a sealing function. The adhesive layer may be made of a polymeric adhesive material, such as silica gel, epoxy resin, benzocyclobutene and other polymeric materials.

In this embodiment, after the first surface 300a of the cover substrate 300 is attached with the first surface 200a of the wafer to be packaged 200, the support structures 320 and the first surface 200a of the wafer to be packaged 200 form the cavities. Positions of the cavities correspond to positions of the sensing regions 211, and an area of the cavity is slightly greater than an area of the sensing region 211, so that the sensing region 211 is located in the cavity. In this embodiment, after the cover substrate 300 is attached with the wafer to be packaged 200, the contact pads 212 on the wafer to be packaged 200 are covered by the support structures 320 on the cover substrate 300. The cover substrate 300 can protect the wafer to be packaged 200 in subsequent processes.

Next, reference is made to FIG. 8. The wafer to be packaged 200 is packaged.

First, the wafer to be packaged 200 is thinned from the second surface 200b of the wafer to be packaged 200 to facilitate subsequent etching for forming the through holes. The wafer to be packaged 200 may be thinned by a mechanical polishing process, a chemical mechanical polishing process, or the like. Then, the wafer to be packaged 200 is etched from the second surface 200b of the wafer to be packaged 200 to form through holes (not indicated), where the contact pads 212 on a side of the first surface 200a of the wafer to be packaged 200 are exposed through the through holes. Next, an insulation layer 213 is formed on the second surface 200b of the wafer to be packaged 200 and side walls of the through holes, where the contact pads 212 at bottoms of the through holes are exposed through the insulation layer 213. The insulation layer 213 can provide electrical insulation for the second surface 200b of the wafer to be packaged 200, and can provide electrical insulation for a substrate of the wafer to be packaged 200 exposed through the through holes. The insulation layer 213 may be made of silicon oxide, silicon nitride, silicon oxynitride or insulating resin. Then, a metal layer 214 connected with the contact pads 212 is formed on a surface of the insulation layer 213. The metal layer 214 may be used as a redistribution layer with which the contact pads 212 are extended to the second surface 200b of the wafer to be packaged 200 for connection to an external circuit. The metal layer 214 is formed by depositing and etching a metal thin film. Next, a solder mask 215 with openings (not indicated) is formed on a surface of the metal layer 214 and the surface of the insulation layer 213, where a portion of the surface of the metal layer 214 is exposed through the openings. The solder mask 215 is made of an insulating dielectric material such as silicon oxide and silicon nitride. The solder mask 215 functions to protect the metal layer 214. Then, protrusions 216 for external connection are formed on a surface of the solder mask 215, where the openings are filled by the protrusions 216 for external connection. The protrusion 216 for external connection may be a connection structure such as a solder ball and a metal pillar, and may be made of a metal material such as copper, aluminum, gold, tin, and lead.

After the wafer to be packaged 200 is packaged, the chip packaging structure obtained by a subsequent cutting process can be connected with an external circuit through the protrusion 216 for external connection. An optical signal is converted by the sensing region 211 of the chip unit into an electrical signal, which sequentially passes through the contact pad 212, the metal layer 214 and the protrusion 216 for external connection and is transmitted to the external circuit for processing.

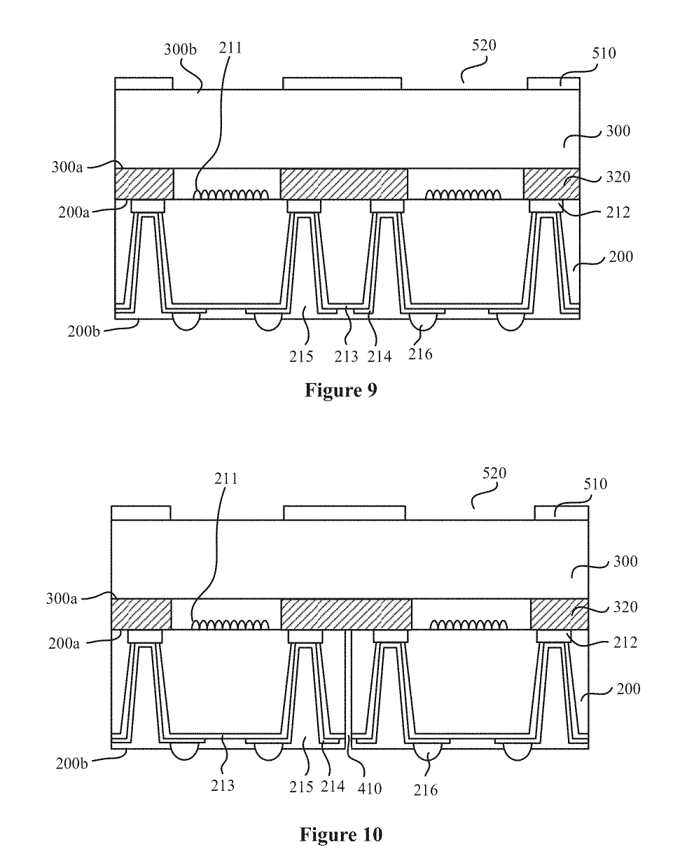

Then, referring to FIG. 9, a light shielding material layer 510 is formed on the second surface 300b of the cover substrate 300, where the light shielding material layer 510 includes multiple openings 520 corresponding to the sensing regions 211. An area of the opening 520 is greater than or equal to an area of the sensing region 211. After packaging structures are formed, the sensing regions 211 are exposed through the openings 520.

In some embodiments, the light shielding material layer 510 is made of a black organic material which is opaque or has low transparency, such as a black sealant. The black organic material is a photosensitive material, and can be patterned by a photolithography process. Specifically, the light shielding material layer 510 may be formed by: forming a black photosensitive organic material layer on the second surface 300b of the cover substrate 300 by spin-coating, spraying or adhering; exposing regions of the black photosensitive organic material layer at which the openings 520 are to be formed, or exposing regions of the black photosensitive organic material layer other than the regions at which the openings 520 are to be formed, according to whether the black photosensitive organic material is positive photoresist or negative photoresist, where the multiple openings 520 corresponding to the sensing regions are formed in the black photosensitive organic material layer after development; and finally, baking the black photosensitive organic material layer for hardening the black photosensitive organic material layer, to improve mechanical strength of the black photosensitive organic material layer and adhesion of the black photosensitive organic material layer to the cover substrate 300. In some embodiments, a thickness of the black photosensitive organic material layer ranges from 10 μm to 50 μm, and preferably, may be 10 μm, 20 μm and the like.

If the light shielding material layer 510 is made of a black sealant, the thickness of the black sealant material layer 510 can be properly increased for achieving better light-shielding effect, since the black sealant is an organic material, which is not completely opaque. However, if the thickness of the black sealant material layer is increased, it is more difficult for light to pass through the black sealant material layer and reach a bottom of the black sealant material layer during exposure, namely, the bottom of the black sealant material layer cannot be completely exposed, which results in increased difficulty in development, thus a resolution of a formed image is affected. In addition, the black sealant is an organic material, from which particles can be easily produced during exposure and development, where the particles may contaminate a chip and cause low transparency.

Therefore, in some other embodiments, the light shielding material layer 510 may be made of metal. The metal may be blackened so that light does not undergo specular reflection at a surface of metal. The metal may be aluminum, aluminum alloy, or other appropriate metal materials. Specifically, the light shielding material layer 510 may be formed by the following steps. A metal material layer is formed on the second surface 300b of the cover substrate 300 by a sputtering process. In this embodiment, the metal material layer is an aluminum layer. Then, the metal material layer is blackened using an acid solution or an alkali solution. For example, the aluminum layer may be processed using an alkali solution including sulfur, to form a black sulfide film on the aluminum layer, thereby improving a light-shielding effect of the aluminum layer. Next, a patterned photoresist layer is formed on the blackened metal material layer, where regions at which the openings 520 are to be formed are exposed through the patterned photoresist layer. Then, the blackened metal material layer is etched with the patterned photoresist layer as a mask, until the second surface 300b of the upper cover substrate 300 is reached, and the patterned photoresist layer is removed to form the light shielding material layer 510 including the multiple openings 520. The blackened metal material provides good light-shielding effect, and has a small thickness, thereby facilitating production of a thin and light packaging structure. In some embodiments, a thickness of the blacked metal material layer ranges from 1 μm to 10 μm, and preferably, may be 5 μm, 6 μm and the like.

It should be noted that, in other embodiments, the light shielding material layer 510 may be formed on the second surface 300b of the cover substrate 300 before the cover substrate 300 is attached with the wafer to be packaged 200, or after a subsequent first cutting process is performed, which is not limited herein and may be selected based on a specific process condition.

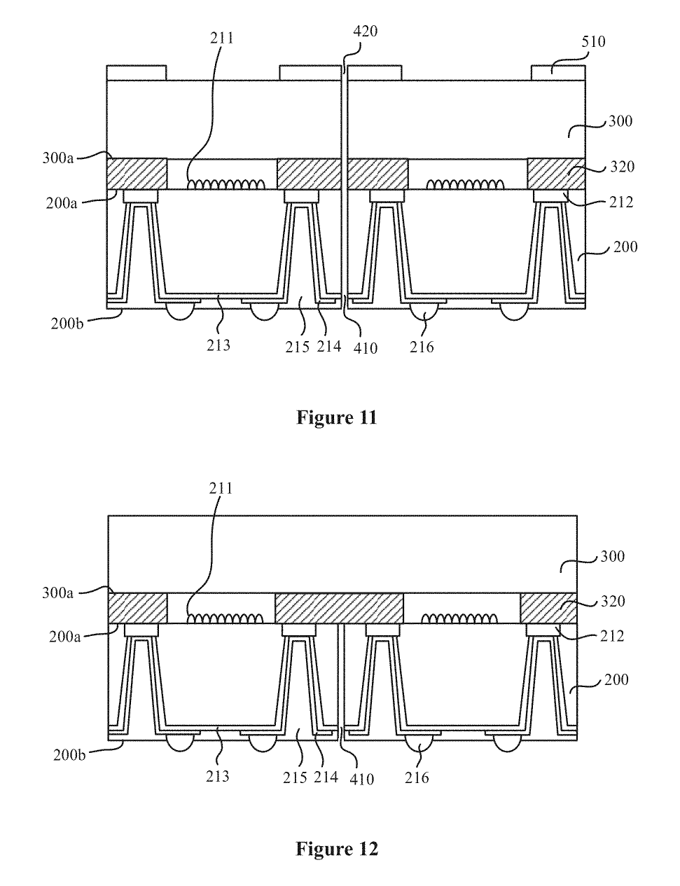

Next, referring to FIGS. 10 and 11, the wafer to be packaged 200, the cover substrate 300, and the light shielding material layer 510 are cut along the cutting channel regions 220 (in combination with FIG. 5) of the wafer to be packaged 200, to form multiple packaging structures as shown in FIG. 2. Each of the packaging structures includes the chip unit 210, the upper cover plate 330 located on the chip unit 210 and formed by cutting the cover substrate 300, and the light shielding layer 511 formed by cutting the light shielding material layer 510. The second surface 330b of the upper cover plate 330 is covered by the light shielding layer 511, and the central region of the second surface 330b corresponding to the sensing region 211 is exposed through the light shielding layer 511.

In this embodiment, the cutting performed on the wafer to be packaged 200, the cover substrate 300 and the light shielding material layer 510 includes a first cutting process and a second cutting process. Specifically, as shown in FIG. 10, the first cutting process is first performed, which includes cutting the wafer to be packaged 200 along the cutting channel regions 220 shown in FIG. 5 from the second surface 200b of the wafer to be packaged 200 until the first surface 200a of the wafer to be packaged 200 is reached, to form a first cutting groove 410. Slicing knife cutting or laser cutting may be used in the first cutting process, where the slicing knife cutting may be performed using a metal knife or a resin knife.

Then, referring to FIG. 11, the second cutting process is performed. The second cutting process includes cutting the light shielding material layer 510 and the cover substrate 300 from the light shielding layer 510 along regions corresponding to the cutting channel regions 220 as shown in FIG. 5, until the first surface 200a of the wafer to be packaged 200 is reached, to form a second cutting groove 420 connected with the first cutting groove 410, and form the multiple packaging structures, by which the cutting process is completed. Slicing knife cutting or laser cutting may be used in the second cutting process.

In some other embodiments, the second cutting process may include cutting the cover substrate 300 and the light shielding material layer 510 along the first cutting groove 410 from the first surface 300a of the cover substrate 300, to form the second cutting groove 420 extending through the cover substrate 300 and the light shielding material layer 510, by which a cutting process is completed.

It should be noted that, in this embodiment, the first cutting process is performed before the second cutting process. In some other embodiments, the first cutting process may be performed after the second cutting process, which is not limited herein.

In addition, a packaging method for forming the packaging structure shown in FIG. 3 is provided according to another embodiment of the present disclosure. Reference is made to FIGS. 12 to 15, which are schematic structural diagrams illustrating a packaging process of the packaging structure shown in FIG. 3 according to another embodiment of the present disclosure.

The embodiment is similar to the previous embodiment. Referring to FIGS. 4 to 8, a wafer to be packaged 200 is provided, where a first surface 200a of the wafer to be packaged 200 includes multiple chip units 210 and cutting channel regions 220 located between the chip units 210, where each of the chip units includes a sensing regions 211; a cover substrate 300 is provided, where multiple support structures 320 are formed on a first surface 300a of the cover substrate 300, and the support structures 320 correspond to the sensing regions 211 on the wafer to be packaged 200; the first surface 300a of the cover substrate 300 is attached with the first surface 200a of the wafer to be packaged 200, so that cavities are formed by the support structures 320 and the first surface 200a of the wafer to be packaged 200, and the sensing regions 211 are located in the cavities. On can refer to the previous embodiment for detailed description, which is not repeated here. Only differences from the previous embodiment are described in detail in the following.

Referring to FIG. 12, after the cover substrate 300 is attached with the wafer to be packaged 200, a first cutting process is performed. The first cutting process includes cutting the wafer to be packaged 200 along the cutting channel regions 220 as shown in FIG. 5 from the second surface 200b of the wafer to be packaged 200 until the first surface 200a of the wafer to be packaged 200 is reached, to form a first cutting groove 410.

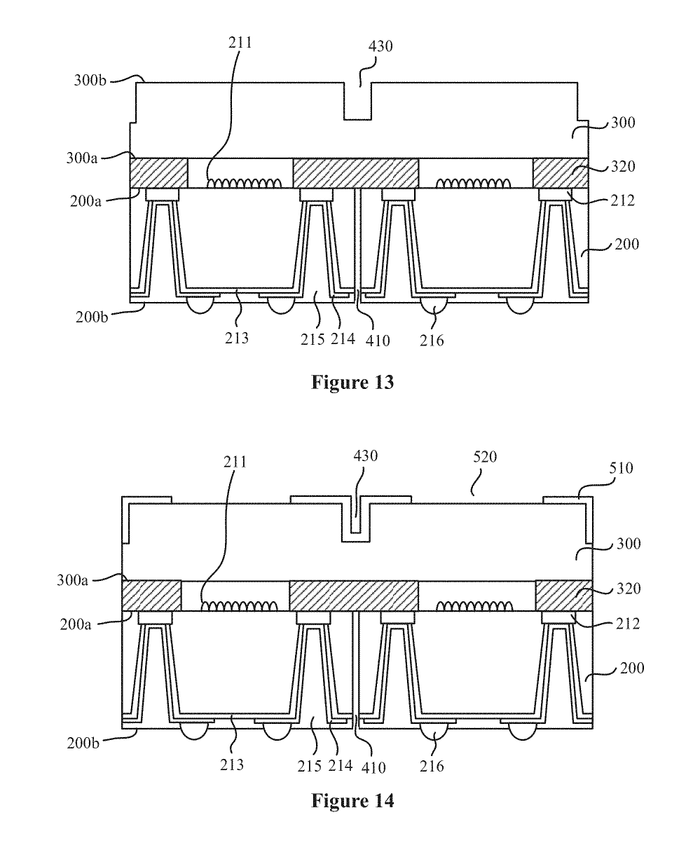

Then, referring to FIG. 13, a third cutting process is performed. The third cutting process includes cutting the cover substrate 300 along the cutting channel regions 220 as shown in FIG. 5 from the second surface 300b of the cover substrate 300 until a preset depth is reached, to form a third cutting groove 430. The third cutting groove 430 is located within the cover substrate 300. A width of the third cutting groove 430 is greater than a width of the first cutting groove 410, and greater than a width of a second cutting groove which is formed subsequently, so that a light shielding material layer may be subsequently formed in the third cutting groove 430. A drill grinding process, a knife cutting process or a laser cutting process may be used for forming the third cutting groove 430.

Then, referring to FIG. 14, a light shielding material layer 510 is formed on the second surface 300b of the cover substrate 300, where the light shielding material layer 510 includes multiple openings 520 corresponding to the sensing regions 211. As compared with the previous embodiment, the light shielding material layer 510 in this embodiment further covers a surface of a sidewall and a surface of a bottom of the third cutting groove 430, so that the light shielding material layer 510 further covers a portion of the sidewall of the upper cover plate after cutting is finished. The light shielding material layer 510 may be made of a black photosensitive organic material or metal.

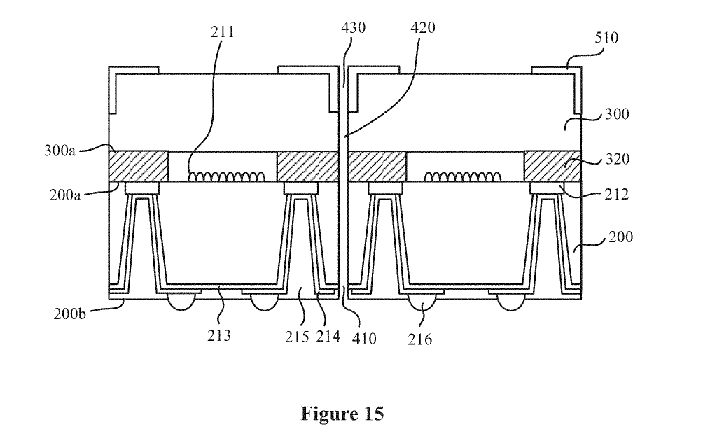

Next, referring to FIG. 15, a second cutting process is performed. The second cutting process includes cutting the light shielding material layer 510 and the cover substrate 300 from the light shielding material layer 510 along regions corresponding to the cutting channel regions 220 shown in FIG. 5 until the first surface 200a of the wafer to be packaged 200 is reached, to form a second cutting groove 420 connected with the first cutting groove 410 and the third cutting groove 430, and form multiple packaging structures, by which the cutting process is finished. In this embodiment, the width of the second cutting groove 420 is less than the width of the third cutting groove 430, so that damage to the light shielding material layer 510 on the surface of the sidewall of the third cutting groove 430 is reduced, and the light shielding material layer 510 on the surface of the sidewall of the third cutting groove 430 is retained in the formed packaging structures. Therefore, referring to FIG. 3, the light shielding layer 511 formed by cutting the light shielding material layer 510 further covers the upper portion of the side wall of the upper cover plate 330 in the final packaging structure. In some embodiments, a height of the upper portion of the sidewall of the upper cover plate 330 covered by the light shielding layer 511 ranges from ⅕ to ⅘ of a thickness of the upper cover plate 330.

It should be noted that, in this embodiment, the first cutting process is performed before the third cutting process and the second cutting process, and in some other embodiments, the first cutting process may be performed after the third cutting process and the second cutting process, or performed between the third cutting process and the second cutting process.

The present disclosure is disclosed above, but is not limited thereto. Various alternations and modifications can be made to the technical solutions of the present disclosure by those skilled in the art without deviation from the spirit and scope of the present disclosure. Therefore, the scope of protection of the present disclosure is defined by the appended claims.

1. A packaging structure, comprising:
a chip unit, wherein a first surface of the chip unit comprises a sensing region;
an upper cover plate, wherein
a first surface of the upper cover plate is provided with a support structure,
the upper cover plate covers the first surface of the chip unit,
the support structure is located between the upper cover plate and the chip unit, and
the sensing region is located in a cavity enclosed by the support structure and the first surface of the chip unit; and
a light shielding layer covering a second surface of the upper cover plate opposite to the first surface of the upper cover plate, wherein a central region of the second surface which overlaps with the sensing region in a light-transmission direction is exposed through the light shielding layer.

2. The packaging structure according to claim 1, wherein an area of the central region of the upper cover plate which is exposed through the shielding layer is greater than or equal to an area of the sensing region.

3. The packaging structure according to claim 1, wherein the shielding layer further covers a portion of a sidewall of the upper cover plate.

4. The packaging structure according to claim 1, wherein the light shielding layer is made of a black photosensitive organic material, and a thickness of the light shielding layer ranges from 10 μm to 50 μm.

5. The packaging structure according to claim 1, wherein the light shielding layer is made of metal, and a thickness of the light shielding layer ranges from 1 μm to 10 μm.

6. The packaging structure according to claim 5, wherein the light shielding layer is made of aluminum.

7. The packaging structure according to claim 5, wherein a surface of the metal is blackened.

8. The packaging structure according to claim 1, wherein the chip unit further comprises:
a contact pad located outside the sensing region;
a through hole extending through the chip unit from a second surface of the chip unit opposite to the first surface of the chip unit, wherein the contact pad is exposed through the through hole;
an insulation layer covering the second surface of the chip unit and a surface of a sidewall of the through hole;
a metal layer located on a surface of the insulation layer and electrically connected to the contact pad;
a solder mask located on a surface of the metal layer and the surface of the insulation layer, wherein the solder mask is provided with an opening through which a portion of the metal layer is exposed; and
a protrusion for external connection by which the opening is filled, wherein the protrusion for external connection is exposed outside a surface of the solder mask.

9. A packaging method for forming a packaging structure, comprising:
providing a wafer to be packaged, wherein a first surface of the wafer to be packaged comprises a plurality of chip units and cutting channel regions located between the plurality of chip units, and each of the plurality of chip units comprises a sensing region;
providing a cover substrate, wherein a plurality of support structures are formed on a first surface of the cover substrate, and the support structures correspond to the sensing regions on the wafer to be packaged;
attaching the first surface of the cover substrate with the first surface of the wafer to be packaged, wherein cavities are formed by the support structures and the first surface of the wafer to be packaged, and the sensing regions are located in the cavities;
forming a light shielding material layer on a second surface of the cover substrate opposite to the first surface of the cover substrate, wherein the light shielding material layer comprises openings corresponding to the sensing regions; and
cutting the wafer to be packaged, the cover substrate, and the light shielding material layer along the cutting channel regions, to form a plurality of packaging structures, wherein each of the plurality of packaging structures comprises one of the plurality chip unit, an upper cover plate formed by cutting the cover substrate, and a light shielding layer formed by cutting the light shielding material layer, the light shielding layer covers a second surface of the upper cover plate, and a central region of the second surface which overlaps with the sensing region in a light-transmission direction is exposed through the light shielding layer.

10. The packaging method according to claim 9, wherein the cutting the wafer to be packaged, the cover substrate, and the light shielding material layer along the cutting channel regions comprises:
performing a first cutting process, which comprises cutting the wafer to be packaged along the cutting channel regions from a second surface of the wafer to be packaged opposite to the first surface of the wafer to be packaged until the first surface of the wafer to be packaged is reached, to form a first cutting groove; and
performing a second cutting process, which comprises cutting the light shielding material layer and the cover substrate to form a second cutting groove connected with the first cutting groove, and form a plurality of packaging structures.

11. The packaging method according to claim 10, wherein the cutting the wafer to be packaged, the cover substrate, and the light shielding material layer along the cutting channel regions further comprises:
performing, before performing the second cutting process, a third cutting process comprising cutting the cover substrate along the cutting channel regions from the second surface of the cover substrate until a preset depth is reached, to form a third cutting groove, wherein:
the light shielding material layer formed on the second surface of the cover substrate covers a sidewall of the third cutting groove,
the second cutting groove formed by cutting the light shielding material layer and the cover substrate with the second cutting process is connected with the first cutting groove and the third cutting groove,
a width of the second cutting groove is less than a width of the third cutting groove, and
the light shielding layer further covers an upper portion of a sidewall of the upper cover plate after the plurality of packaging structures are formed.

12. The packaging method according to claim 9, wherein the light shielding material layer is made of a black photosensitive organic material, and the forming the light shielding material layer on the second surface of the cover substrate comprises:
forming a black photosensitive organic material layer on the second surface of the cover substrate, by a spin coating process, a spraying process, or an adhesion process;
exposing and developing the black photosensitive organic material layer, to form openings corresponding to the sensing regions in the black photosensitive organic material layer; and
baking the black photosensitive organic material layer for hardening the black photosensitive organic material layer.

13. The packaging method according to claim 9, wherein the light shielding material layer is made of metal, and the forming the light shielding material layer on the second surface of the cover substrate comprises:
forming a metal material layer on the second surface of the cover substrate by a sputtering process;
forming a patterned photoresist layer on the metal material layer, wherein regions of the metal material layer at which the openings are to be formed are exposed through the patterned photoresist layer;
etching the metal material layer with the patterned photoresist layer as a mask, until the second surface of the cover substrate is exposed, to form the openings corresponding to the sensing regions; and
removing the patterned photoresist layer.

14. The packaging method according to claim 13, further comprising: blackening a surface of the metal material layer using an acid solution or an alkali solution.

15. The packaging method according to claim 9, wherein each of the plurality of chip units further comprises a contact pad located outside the sensing region, and after attaching the first surface of the cover substrate with the first surface of the wafer to be packaged, the packaging method further comprises:
thinning the wafer to be packaged from a second surface of the wafer to be packaged opposite to the first surface of the wafer to be packaged;
etching the wafer to be packaged from the second surface of the wafer to be packaged, to form through holes through which the contact pads of the plurality of chip units are exposed;
forming an insulation layer on the second surface of the wafer to be packaged and surfaces of sidewalls of the through holes;
forming a metal layer connected to the contact pads on a surface of the insulating layer;
forming a solder mask on a surface of the metal layer and the surface of the insulation layer, wherein the solder mask comprises openings through which a portion of the surface of the metal layer is exposed; and
forming protrusions for external connection on a surface of the solder mask, wherein the openings are filled by the protrusions for external connection.
